(19) United States
(12) Patent Application Publication
(10) Pub. No.: US 2018/0095320 A1
(43) Pub. Date: Apr. 5, 2018

(54) LIQUID CRYSTAL DISPLAY PANLE, TFT SUBSTRATE AND MANUFACTURING METHOD THEREOF

(71) Applicant: Wuhan China Star Optoelectronics Technology Co., Ltd., Wuhan, Hubei (CN)

(72) Inventor: Yingtao XIE, Shenzhen, Guangdong (CN)

(73) Assignee: Wuhan China Star Optoelectronics Technology Co., Ltd., Wuhan, Hubei (CN)

(21) Appl. No.: 15/109,903

(22) PCT Filed: Jun. 12, 2016
(86) PCT No.: PCT/CN2016/085465

§ 371 Date: Jul. 6, 2016

(30) Foreign Application Priority Data
Jan. 29, 2016 (CN) 201610064926.6

(51) Int. Cl. G02F 1/1333; H01L 21/77; H01L 27/12

(52) U.S. Cl. CPC G02F 1/133345; H01L 2021/775; H01L 27/1259; H01L 21/77

(57) ABSTRACT

The invention provides a manufacturing method of a TFT substrate. The manufacturing method includes: disposing a groove on a base; filling a metal material in the groove to form a first metal layer, the first metal layer acting as a gate of the TFT substrate; disposing an insulating layer on the first metal layer and the base; sequentially disposing a semiconductor material layer and a second metal layer on the insulating layer, the second metal layer forming a drain and a source of the TFT substrate, and the semiconductor material layer being disposed between the drain and the gate. The invention further provides a liquid crystal display panel and a TFT substrate. By the above means, the invention can reduce the thickness of the TFT substrate, which is beneficial to the realization of ultra-thin liquid crystal display panel and can improve display panel of the liquid crystal display panel.

### TECHNICAL FIELD

The invention relates to the field of liquid crystal technology, and particularly to a liquid crystal display panel, a TFT substrate and a manufacturing method thereof.

### DESCRIPTION OF RELATED ART

Liquid crystal display panels are a type of currently most widely used flat panel display panel, and thus have gradually become display panels having high-resolution color screen and being widely used for a variety of electronic devices such as mobile phones, personal digital assistants (PDAs), digital cameras, computer screens or laptop screens. With the development and progress of the liquid crystal display panel technology, people are putting forward higher requirements towards display quality, appearance design, low cost and high transmittance for liquid crystal display panels.

Low-power and ultra-thin liquid crystal display panels have become the trend in the field of liquid crystal display technology. As illustrated in FIG. 1, a TFT substrate (thin film transistor array substrate) of a liquid crystal display panel in the current display field includes a base 11, a first metal layer 12 disposed on the base 11, an insulating layer 13 disposed on the first metal layer 12, a semiconductor material layer 14 disposed on the insulating layer 13, and a second metal layer 15 disposed on the semiconductor material layer 14. Since the first metal layer 12 is disposed on the base 11 and the insulating layer 13 is disposed on the first metal layer 12, which makes a thickness of the TFT substrate be relatively large and thus goes against the realization of ultra-thin liquid crystal display panel. Moreover, the film quality of the insulating layer 13 at the corners of the first metal layer 12 is relatively poor, it is easily broken down by a driving voltage and thus also would affect display quality of the liquid crystal display panel.

In summary, it is necessary to provide a liquid crystal display panel, a TFT substrate and a manufacturing method thereof so as to solve the aforementioned problems.

### SUMMARY

Technical problems mainly to be solved by the invention are to provide a liquid crystal display panel, a TFT substrate and a manufacturing method thereof, which can achieve an ultra-thin liquid crystal display panel and improve display quality of the liquid crystal display panel.

In order to solve the above technical problems, a technical solution proposed by the invention is to provide a manufacturing method of a TFT substrate. The manufacturing method includes: disposing a groove on a base; filling a metal material in the groove to form a first metal layer, the first metal layer being as a gate of the TFT substrate; disposing an insulating layer on the first metal layer and the base; sequentially disposing a semiconductor material layer and a second metal layer on the insulating layer, the second metal layer being as a drain and a source of the TFT substrate, the semiconductor material layer being disposed between the drain and the gate.

In an embodiment, a thickness of the first metal layer is less than or equal to a depth of the groove.

In an embodiment, a difference between the thickness of the first metal layer and the depth of the groove is in a range of 0-20 nm.

In an embodiment, the step of disposing a groove on the base includes: coating a photoresist on the base; and etching a region of the base without being coated with the photoresist by a dry etching process or a wet etching process to form the groove.

In an embodiment, the step of filling a metal material in the groove to form a first metal layer includes: depositing a metal material on the groove by a magnetron sputtering process or a thermal evaporation process; immersing the base into a photoresist-removing solution to remove the photoresist coated on the base by the photoresist-removing solution and thereby forming the first metal layer in the groove.

In an alternative embodiment, the step of filling a metal material in the groove to form a first metal layer includes: immersing the base into a photoresist-removing solution to remove the photoresist coated on the base by the photoresist-removing solution; and dropping a metal conductive ink into the groove by an ink-jet printing process to form the first metal layer in the groove.

In order to solve the above technical problems, another technical solution proposed by the invention is to provide a TFT substrate. The TFT substrate includes: a base disposed with a groove; a first metal layer disposed on the base, the first metal layer being disposed in the groove and as a gate of the TFT substrate; an insulating layer disposed on the first metal layer and the base; and a semiconductor material layer and a second metal layer sequentially disposed on the insulating layer, the second metal layer forming a drain and a source of the TFT substrate, the semiconductor material layer being disposed between the drain and the gate.

In an embodiment, a thickness of the first metal layer is less than or equal to a depth of the groove.

In an embodiment, a difference between the thickness of the first metal layer and the depth of the groove is in a range of 0-20 nm.

In order to solve the above problems, still another technical solution proposed by the invention is to provide a liquid crystal display panel. The liquid crystal display panel includes the above described TFT substrate.

The efficacy achieved by the invention is that: distinguished from the prior art, the manufacturing method of a TFT substrate according to the invention includes: disposing a groove on a base; filling a metal material in the groove to form a first metal layer; disposing an insulating layer on the first metal layer and the base; and sequentially disposing a semiconductor material layer and a second metal layer on the insulating layer. By the above means, the invention disposes the first metal layer in the base, which can reduce a thickness of the TFT substrate and is beneficial to the realization of ultra-thin liquid crystal display panel; meanwhile since the first metal layer is disposed in the base, thicknesses of the insulating layer above corners of the first meta layer are consistent and thus the insulating layer is not easily broken down the a driving voltage, so that the display quality of the liquid crystal display panel can be effectively improved.

### BRIEF DESCRIPTION OF THE DRAWINGS

FIG. 1 is a schematic structural view of a TFT substrate in the related art.

FIG. 2 is a schematic structural view of a first embodiment of a TFT substrate according to the invention.

FIG. 3 is a schematic structural view of a second embodiment of the TFT substrate according to the invention.

FIG. 4 is a flowchart of a manufacturing method of the TFT substrate according to the invention.

FIG. 5 is a schematic view of a resultant structure corresponding to step S101 in FIG. 4.

FIG. 6 is a flowchart of sub-steps of the step S101 in FIG. 4.

FIG. 7 is a schematic view of a resultant structure corresponding to step S102 in FIG. 4.

FIG. 8 is a flowchart of a first embodiment of sub-steps of the step S102 in FIG. 4.

FIG. 9 is a flowchart of a second embodiment of sub-steps of the step S102 in FIG. 4.

FIG. 10 is a schematic view of a resultant structure corresponding to step S103 in FIG. 4.

FIG. 11 is a flowchart of a first embodiment of sub-steps of step S104 in FIG. 4.

FIG. 12 is a schematic view of a resultant structure corresponding to sub-step S1041 in FIG. 11.

FIG. 13 is a schematic view of a resultant structure corresponding to sub-step S1042 in FIG. 11.

FIG. 14 is a flowchart of a second embodiment of sub-steps of step S104 in FIG. 4.

FIG. 15 is a schematic view of a resultant structure corresponding to sub-step S2041 in FIG. 14.

FIG. 16 is a schematic view of a resultant structure corresponding to sub-step S2042 in FIG. 14.

### DETAILED DESCRIPTION OF EMBODIMENTS

In order to make technical problems to be solved, technical solutions and beneficial effects of the invention be more clear and apparent, in the following, in conjunction with accompanying drawings and embodiments, the invention will be further described in detail. It should be understood that, specific embodiments described herein are merely to illustrate the invention and not intended to limit the invention.

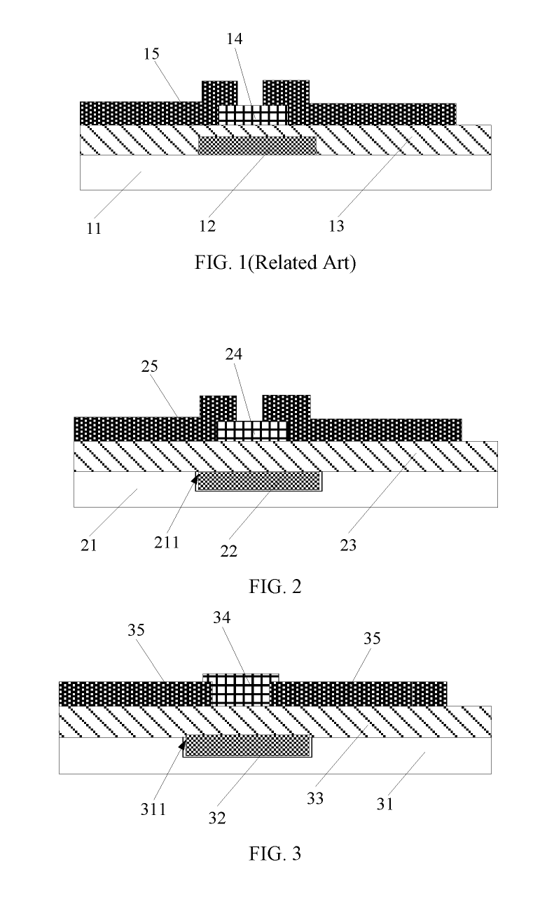

The invention discloses a liquid crystal display panel. The liquid crystal display panel includes a CF substrate (color filter array substrate) and a TFT substrate (thin film transistor array substrate) spacedly disposed from each other. As illustrated in FIG. 2 which is a schematic structural view of a first embodiment of the TFT substrate according to the invention. The TFT substrate includes a base 21, a first metal layer 22, an insulating layer 23, a semiconductor material layer 24 and a second metal layer 25.

The base 21 is disposed with a groove 211, and the first metal layer 22 is disposed in the groove 211. The first metal layer 22 acts as a gate of the TFT substrate. In the illustrated embodiment, a thickness of the first metal layer 22 is less than or equal to a depth of the groove 211, and preferably a difference value between the thickness of the first metal layer 22 and the depth of the groove 211 is in the range of 0-20 nanometers, i.e., the thickness of the first metal layer 22 is less than the depth of the groove 211 with 0-20 nanometers. It should be understood that, the invention is not limited to be that the thickness of the first metal layer 22 is less than the depth of the groove 211 with 0-20 nanometers, and in other embodiment, concrete values of the thickness of the first metal layer 22 and the depth of the groove 211 can be specifically set according to actual requirement.

It should be understood that, the invention is not limited to be that the thickness of the first metal layer 22 is less than or equal to the depth of the groove, and in other embodiment, the thickness of the first metal layer 22 may be greater than the depth of the groove 211 instead. Preferably, the thickness of the first metal layer 22 is greater than the depth of the groove 211 with 0-20 nanometers, and of course, concrete values of the thickness of the first metal layer 22 and the depth of the groove 211 can be specifically set according to actual requirement.

The insulating layer 23 is disposed on the first metal layer 22 and the base 21. In the illustrated embodiment, a thickness of the insulating layer 23 is in the range of 5-500 nanometers.

The semiconductor material layer 24 is disposed on the insulating layer 13. In the illustrated embodiment, a thickness of the semiconductor material layer 24 is in the range of 10-200 nm.

The second metal layer 25 is disposed on the semiconductor material layer 24. The second metal layer 25 forms a drain and a source of the TFT substrate, and the semiconductor material layer 24 is disposed between the drain and the gate. In the illustrated embodiment, a thickness of the second metal layer 25 is in the range of 100-300 nanometers.

The illustrated embodiment disposes the first metal layer in the base, which makes the thickness of the TFT substrate be reduced, can solve the problem of insulating layer being not easily deposited at the corners of the traditional protruded first metal layer, and meanwhile can reduce the thickness of the insulating layer to increase a capacitance between the first metal layer and the second metal layer, reduce the driving voltage of the TFT substrate and improve display quality of the liquid crystal display panel.

Referring to FIG. 3, which is a schematic structural view of a second embodiment of the TFT substrate according to the invention. A main difference of the TFT substrate shown in FIG. 3 from the TFT substrate shown in FIG. 2 is that: a second metal layer 35 is disposed on an insulating layer 33, a semiconductor material layer 34 is disposed on the second metal layer 35, and a thickness of the first metal layer 32 is greater than a depth of a groove 311.

It should be understood that, since the thickness of the first metal layer 32 is greater than the depth of the groove 311, a part of the first metal layer 32 is exposed above the base 31. In order to avoid the problem of the insulating layer 33 being not easily deposited at corners of protruding first metal layer 32, the illustrated embodiment cuts off the protruding corners of the first metal layer 32, i.e., the corner portions of the first metal layer 32 are cut to be with an oblique angle, which facilitates the deposition of insulating layer. Of course, in other embodiment, the groove may be not disposed, and the corner portions of the first metal layer 32 are directly cut to be with an oblique angle, facilitating the deposition of insulating layer.

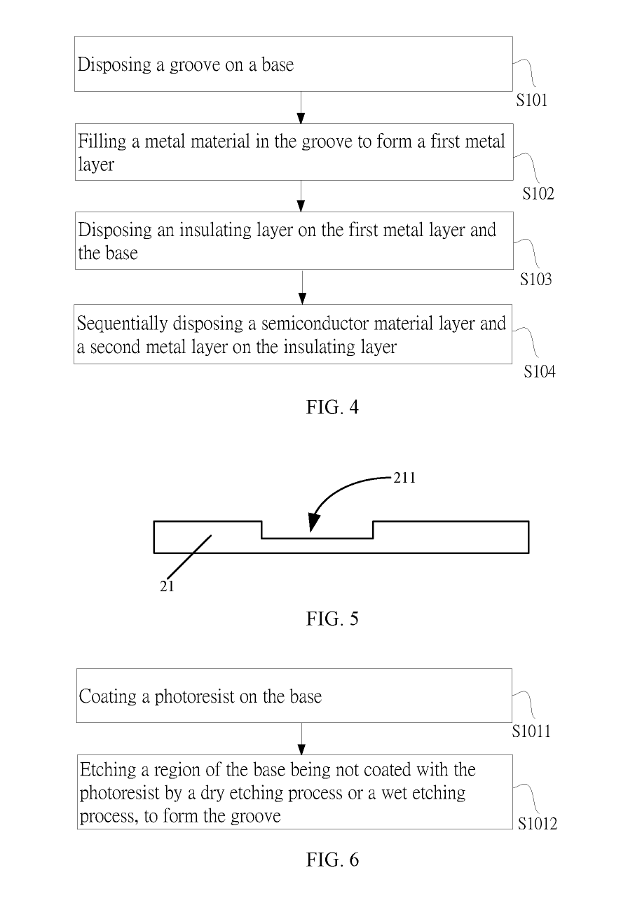

In order to more clearly understand the invention, a manufacturing process of the TFT substrate will be described below in detail. Referring to FIG. 4, which is a flowchart of a manufacturing method of the TFT substrate according to the invention. The manufacturing method includes following steps.

Step S101: disposing a groove 211 on a base 21.

A resultant structure corresponding to the step S101 is shown in FIG. 5, the groove 211 is directly formed on the base 21 and concrete sub-steps are shown in FIG. 6. The step S101 includes the following sub-steps S1011 and S1012.

Sub-step S1011: coating a photoresist on the base 21. The photoresist can protect the base from being etched by photolithography.

Sub-step S1012: etching a region of the base 21 being not coated with the photoresist by a dry etching process or a wet etching process to form the groove 211.

It should be understood that, in the sub-step S1012, the dry etching process or the wet etching process can etch out the groove 211 with vertical corners.

Step S102: filling a metal material in the groove 211 to form a first metal layer 22. The first metal layer 22 acts as a gate of the TFT substrate.

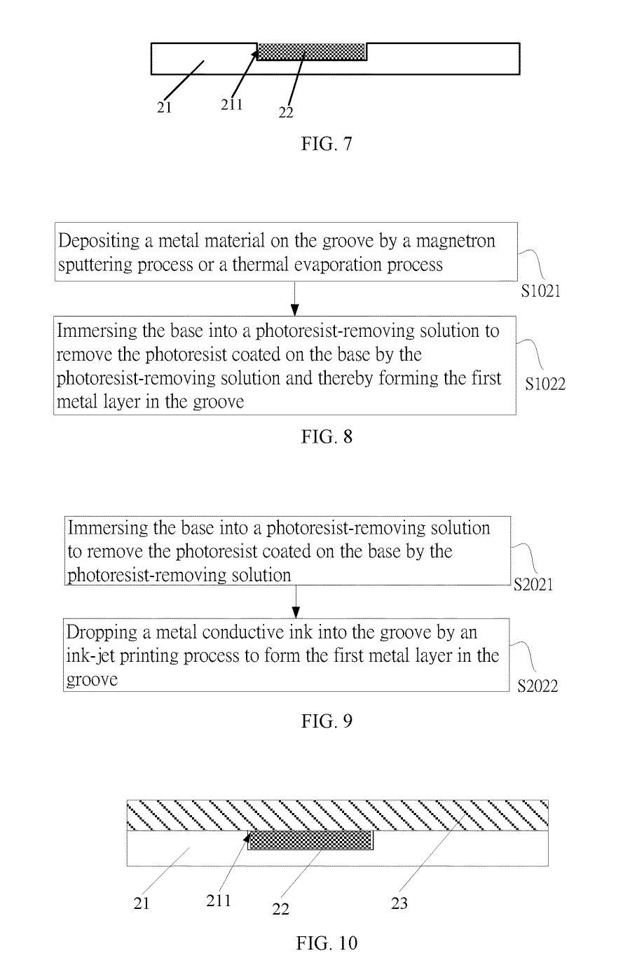

A resultant structure corresponding to the step S102 is shown in FIG. 7, the metal material is filled into the groove 211 to form the first metal layer 22 and concrete sub-steps are shown in FIG. 8. The step S102 for example includes the following sub-steps S1021 and S1022.

Sub-step S1021: depositing a metal material on the groove 211 by a magnetron sputtering process or a thermal evaporation process.

Sub-step S1022: immersing the base 21 into a photoresist-removing solution to remove the photoresist coated on the base 21 by the photoresist-removing solution, and thereby the first metal layer 22 is formed in the groove 211.

It should be understood that, in order to realize the resultant structure as shown in FIG. 7, in other embodiment, as shown in FIG. 9, the step S102 may include the following sub-steps S2021 and S2022 instead.

Sub-step S2021: immersing the base 21 in a photoresist-removing solution to remove the photoresist coated on the base 21 by the photoresist-removing solution.

Sub-step S2022: dropping a metal conductive ink into the groove 211 by an ink-jet printing process to form the first metal layer 22 in the groove 211.

In the illustrated embodiment, a thickness of the first metal layer 22 is less than or equal to a depth of the groove 211. Preferably, a difference between the thickness of the first metal layer 22 and the depth of the groove 211 is in a range of 0-20 nm, i.e., the thickness of the first metal layer 22 is less than the depth of the groove 211 with the range of 0-20 nm. It should be understood that, the invention is not limited to be that the thickness of the first metal layer 22 is less than the depth of the groove 211 with the range of 0-20 nm, it can particularly set concrete values of the thickness of the first metal layer 22 and the depth of the groove 211 according to actual requirement. Of course, in other embodiment, the thickness of the first metal layer 22 may be greater than the depth of the groove 211, and preferably the thickness of the first metal layer 22 is greater than the depth of the groove 211 with the range of 0-20 nm, and further concrete values of the thickness of the first metal layer 22 and the depth of the groove 211 can be particularly set according to actual requirement.

Step S103: disposing an insulating layer 23 on the first metal layer as well as the base 21.

In the step S103, the insulating layer 23 with a thickness in a range of 5-500 nm is formed on the first metal layer 22 and the base 21 by a magnetron sputtering process, a plasma enhanced chemical vapor deposition (PECVD) process, an atomic layer deposition (ALD) process or a solution method process.

Step S104: sequentially disposing a semiconductor material layer 24 and a second metal layer 25 on the insulating layer 23. The second metal layer 25 forms a drain and a drain and a source of the TFT substrate, and the semiconductor material layer 24 is disposed between the drain and the gate.

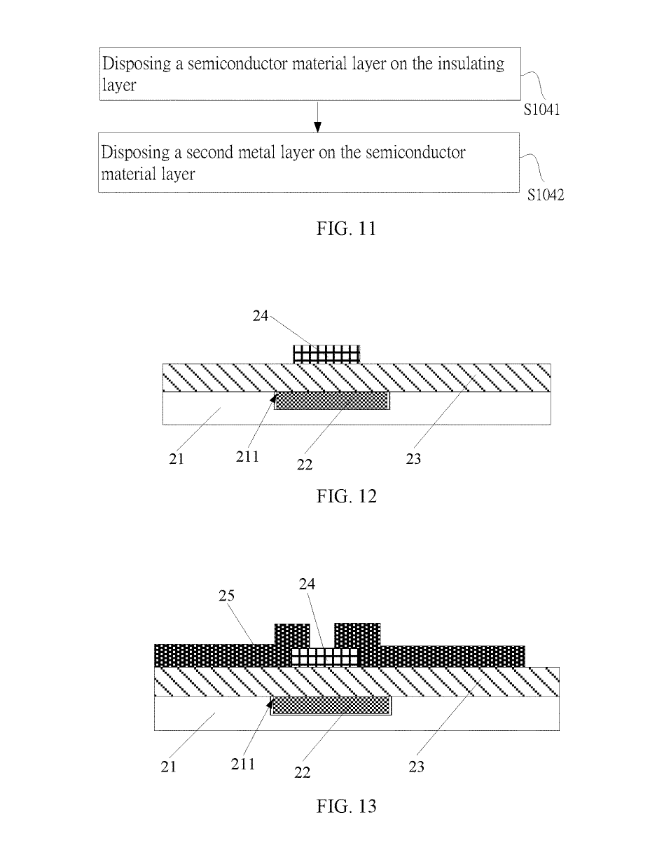

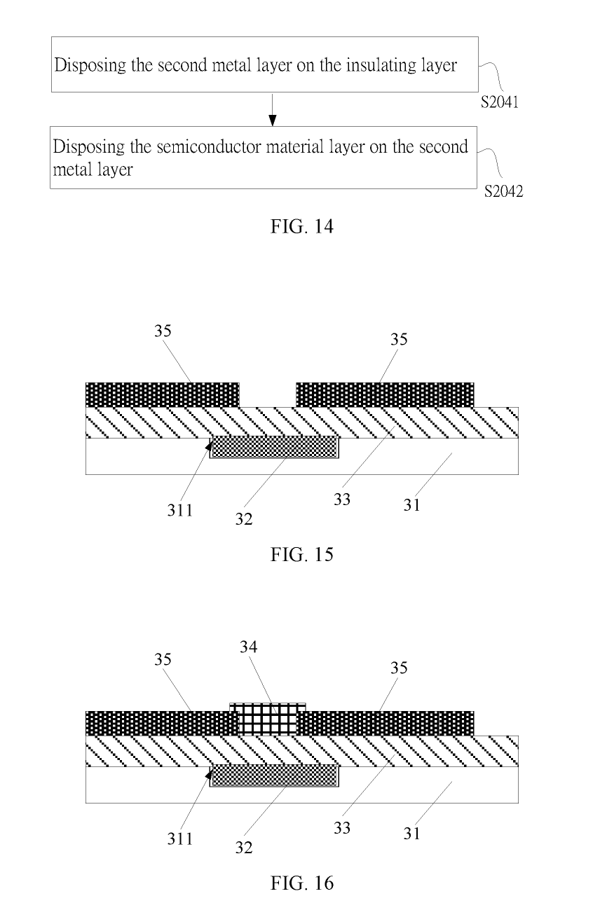

As illustrated in FIG. 11, the step S104 includes the following sub-steps S1041 and S1042.

Sub-step S1041: disposing the semiconductor material layer 24 on the insulating layer 23.

A resultant structure corresponding to the sub-step S1041 is shown in FIG. 12, and the semiconductor material layer 24 is directly formed on the insulating layer 23.

In the sub-step S1041, the semiconductor material layer 24 with a thickness in a range of 10-200 nm is formed on the insulating layer 23 by a magnetron sputtering process, a plasma enhanced chemical vapor deposition process, an atomic layer deposition process or a solution method process.

Sub-step S1042: disposing the second metal layer 25 on the semiconductor material layer 24.

A resultant structure corresponding to the sub-step S1042 is shown in FIG. 13, and the second metal layer 25 is directly formed on the semiconductor material layer 24.

In the sub-step S1042, the second metal layer 25 with a thickness in a range of 100-300 nm is formed on the semiconductor material layer 24 by a magnetron sputtering process, an atomic layer deposition process or a solution method process.

It should be understood that, in other embodiment, the step S104 may include the following sub-steps S2041 and S2041 instead.

Sub-step S2041: disposing the second metal layer 35 on the insulating layer 33.

A resultant structure corresponding to the sub-step S2041 is shown in FIG. 15, and the second metal layer 35 is directly formed on the insulating layer 33.

In the sub-step S2041, the second metal layer 35 with a thickness in a range of 100-300 nm is formed on the insulating layer 33 by a magnetron sputtering process, an atomic layer deposition process or a solution method process.

Sub-step S2042: disposing the semiconductor material layer 34 on the second metal layer 35.

A resultant structure corresponding to the sub-step S2042 is shown in FIG. 16, and the semiconductor material layer 34 is directly formed on the second metal layer 35.

In the sub-step S2042, the semiconductor material layer 34 with a thickness in a range of 10-200 nm is formed on the second metal layer 35 by a magnetron sputtering process, a plasma enhanced chemical vapor deposition process, an atomic layer deposition process or a solution method process.

The illustrated embodiment disposes the first metal layer in the base, so that the thickness of the TFT substrate is reduced, which solves the problem of insulating layer being not easily deposited at corners of the conventional protruded first metal layer, and meanwhile can increase a capacitance between the first metal layer and the second metal layer, reduce a driving voltage of the TFT substrate and improve display quality of the liquid crystal display panel.

In summary, the manufacturing method of a TFT substrate according to the invention includes: disposing a groove on the base; filling a metal material in the groove to form a first metal layer; disposing an insulating layer on the first metal layer and the base; and sequentially disposing a semiconductor material layer and the a second metal layer on the insulating layer. By the above solution, the invention disposes the first metal layer in the base, which can reduce the thickness of the TFT substrate and is beneficial to the realization of ultra-thin liquid crystal display panel; meanwhile, since the first metal layer is disposed in the base, the thicknesses of the insulating layer above the corners of the first metal layer are consistent and thus is not easily broken down by driving voltage, so that display quality of the liquid crystal display panel can be effectively improved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A manufacturing method of a TFT substrate, comprising:
disposing a groove on a base;
filling a metal material in the groove to form a first metal layer, wherein the first metal layer acts as a gate of the TFT substrate;
disposing an insulating layer on the first metal layer and the base;
sequentially disposing a semiconductor material layer and a second metal layer on the insulating layer, wherein the second metal forms a drain and a source of the TFT substrate, and the semiconductor material layer is disposed between the drain and the gate.

2. The manufacturing method as claimed in claim 1, wherein a thickness of the first metal layer is less than or equal to a depth of the groove.

3. The manufacturing method as claimed in claim 2, wherein a difference between the thickness of the first metal layer and the depth of the groove is in a range of 0-20 nm.

4. The manufacturing method as claimed in claim 1, wherein the step of disposing a groove on the base comprises:
coating a photoresist on the base;
etching a region of the base being not coated with the photoresist by a dry etching process or a wet etching process to form the groove.

5. The manufacturing method as claimed in claim 4, wherein the step of filling a metal material in the groove to form a first metal layer comprises:
depositing the metal material on the groove by a magnetron sputtering process or a thermal evaporation process;
immersing the base into a photoresist-removing solution to remove the photoresist coated on the base by the photoresist-removing solution and thereby forming the first metal layer in the groove.

6. The manufacturing method as claimed in claim 4, wherein the step of filling a metal material in the groove to form a first metal layer comprises:
immersing the base into a photoresist-removing solution to remove the photoresist coated on the base by the photoresist-removing solution;
dropping a metal conductive ink into the groove by an ink-jet printing process to form the first metal layer in the groove.

7. A TFT substrate comprising:
a base disposed with a groove;
a first metal layer disposed on the base, wherein the first metal layer is disposed in the groove, and the first metal layer acts as a gate of the TFT substrate;
an insulating layer disposed on the first metal layer and the base;
a semiconductor material layer and a second metal layer sequentially disposed on the insulating layer, wherein the second metal layer forms a drain and a source of the TFT substrate, and the semiconductor material layer is disposed between the drain and the gate.

8. The TFT substrate as claimed in claim 7, wherein a thickness of the first metal layer is less than or equal to a depth of the groove.

9. The TFT substrate as claimed in claim 8, wherein a difference between the thickness of the first metal layer and the depth of the groove is in a range of 0-20 nm.

10. A liquid crystal display panel comprising the TFT substrate as claimed in claim 7.
